(19) United States
(12) Patent Application Publication
(10) Pub. No.: US 2008/0196667 A1
(43) Pub. Date: Aug. 21, 2008

(54) EVAPORATION DEVICE FOR EVAPORATING VAPOR DEPOSITION MATERIALS

(75) Inventor: Toshiaki FUKUNAGA, Ashigarakami-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/030,286

(22) Filed: Feb. 13, 2008

(30) Foreign Application Priority Data
Feb. 15, 2007 (JP) 034978/2007

(51) Int. Cl. C23C 16/54

(52) U.S. Cl. 118/724

(57) ABSTRACT

An evaporation device for evaporating vapor deposition materials by heating is disclosed. The evaporation device includes deposition vessels each containing a different vapor deposition material, a heating unit for heating the vapor deposition materials contained in the deposition vessels, and a common opening area including a common opening, through which the vapor deposition materials evaporated in the deposition vessels exit together.

### BACKGROUND OF THE INVENTION

1. Field of the Invention

The present invention relates to an evaporation device for evaporating vapor deposition materials, which heats film-forming materials in a vacuum deposition chamber to evaporate the materials so that the evaporated materials are deposited on a member subjected to deposition, such as a substrate.

2. Description of the Related Art

Apparatuses for depositing film-forming materials on a substrate, or the like, through vacuum vapor deposition are used in various fields. In recent years, radiographic image detectors using a photoconductor, which is sensitive to radiation such as X-ray, have been used for medical radiography, and vacuum vapor deposition apparatuses have been used for manufacturing such detectors.

In order to reduce an exposure dose of the radiation applied to a subject and to improve diagnosis performance, the radiographic image detector uses a photoconductor, such as selenium, which is sensitive to radiation as a photoreceptor to store electric charges of amounts proportional to an applied radiation dose, and the detector electrically reads out the stored electric charges. This type of radiographic image detectors have been widely known and applied for patent. For example, U.S. Pat. No. 6,770,901 has proposed a radiographic image detector, which includes: a first electrode layer that transmits radiation therethrough; a photoconductive recording layer that generates electric charges when being exposed to the radiation; a charge transport layer that functions as an insulator for electric charges of a latent image and as a conductor for transporting charges of a polarity reverse to that of the latent image charges; a photoconductive reading layer that generates electric charges when being exposed to reading light; and a second electrode layer formed by linearly extending transparent linear electrodes that transmit the reading light therethrough and linearly extending light-blocking linear electrodes that block the reading light, which are arranged alternately and in parallel with each other. These layers are disposed in this order.

It is known for such a radiographic image detector that doping the Se photoconductive layer of the radiographic image detector with 0.35% of As is effective to stabilize the amorphous state, as shown in Journal of Non-Crystalline Solids 266-269 (2000) 1163-1167, for example. Further, it is known from Japanese Unexamined Patent Publication No. 2002-329848 that providing a thin layer of Se doped with 0.5-40 atom % of As between the photoconductive reading layer and the second electrode layer is effective for preventing crystallization at the interface of the photoconductive reading layer.

In this type of radiation detector, uniformity is very important for improving the diagnosis performance of medical images used for diagnosis. That is, in a case where a deposited film of a compound containing two or more vapor deposition materials, as described above, is formed, it is desirable that the component ratio of the vapor deposition materials is uniform throughout the deposited film surface.

In order to form a film having a uniform component ratio using two or more vapor deposition materials, such as in a case where Se is doped with As, a mixture of Se and As contained in a single evaporation vessel may be evaporated. However, in this case, fractionation occurs due to different vapor pressures of the different component elements, and the component ratio of the deposited film changes as the deposition progresses. In order to address this problem, Japanese Unexamined Patent Publication No. 61(1986)-273829 proposes a method for forming a deposited film of a compound containing more than one vapor deposition materials, wherein a plurality of deposition vessels, each containing a different vapor deposition material, are disposed with a certain space therebetween to deposit the vapor deposition materials in the respective deposition vessels on a substrate.

In the above-described conventional technique, in which the deposition vessels, each containing a different vapor deposition material, are disposed with a certain space therebetween and the vapor deposition materials in the respective deposition vessels are deposited on a substrate to form a deposited film of a compound containing more than one vapor deposition materials, however, distances from the respective deposition vessel to each point on the deposition substrate are not the same. Therefore, there still is the problem of non-uniform component ratio of the vapor deposition materials throughout the deposited film surface.

### SUMMARY OF THE INVENTION

In view of the above-described circumstances, the present invention is directed to provide an evaporation device for evaporating vapor deposition materials, which allows formation of a deposited film having a uniform component ratio of a compound of more than one vapor deposition materials.

An aspect of the evaporation device for evaporating vapor deposition materials of the invention includes: a plurality of deposition vessels each containing a different vapor deposition material; a heating unit for heating the vapor deposition materials contained in the deposition vessels; and a common opening area including a common opening, the vapor deposition materials evaporated in the deposition vessels exiting together through the common opening.

Another aspect of the evaporation device for evaporating vapor deposition materials of the invention includes: a plurality of deposition vessels each containing a different vapor deposition material, the deposition vessels having their openings arranged side by side; and a heating unit for heating the vapor deposition materials contained in the deposition vessels.

It should be noted that the “openings arranged side by side” is not limited to those completely contacting to each other, and includes a case where the openings can be considered as substantially contacting to each other even if a slight space is present between the openings. For example, “openings disposed side by side” includes a case where a space of 10 mm or less is present between the openings.

In the above-described device, heating of each deposition vessel by the heating unit may be independently controllable.

### BRIEF DESCRIPTION OF THE DRAWINGS

FIG. 1 is a schematic diagram illustrating the schematic structure of a vapor deposition apparatus including an evaporation device for evaporating vapor deposition materials of a first embodiment,

FIG. 2A is a perspective view, FIG. 2B is a plan view and FIG. 2C is a sectional view of the evaporation device for evaporating vapor deposition materials of the first embodiment,

FIG. 3 is a sectional view illustrating a first modification of the evaporation device for evaporating vapor deposition materials of the first embodiment,

FIG. 4 is a sectional view illustrating a second modification of the evaporation device for evaporating vapor deposition materials of the first embodiment,

FIG. 5 is a schematic diagram illustrating the schematic structure of a vapor deposition apparatus including an evaporation device for evaporating vapor deposition materials of a second embodiment,

FIG. 6A is a perspective view, FIG. 6B is a plan view and FIG. 6C is a sectional view of the evaporation device for evaporating vapor deposition materials of the second embodiment,

FIG. 7 is a sectional view illustrating a modification of the evaporation device for evaporating vapor deposition materials of the second embodiment,

FIG. 8 is a plan view illustrating a first arrangement example of the evaporation devices with respect to a substrate,

FIG. 9 is a plan view illustrating a second arrangement example of the evaporation devices with respect to a substrate,

FIG. 10A is a perspective view illustrating the schematic structure of an optical reading radiographic image detector,

FIG. 10B is a sectional view of the radiographic image detector of FIG. 10A taken along the X-Z plane,

FIG. 10C is a sectional view of the radiographic image detector of FIG. 10A taken along the X-Y plane,

FIG. 11A is a diagram illustrating the schematic structure of a TFT radiographic image detector,

FIG. 11B is a sectional view illustrating the structure of the radiographic image detector of FIG. 11A corresponding to a pixel, and

FIG. 11C is a plan view illustrating the structure of the radiographic image detector of FIG. 11A corresponding to a pixel.

### DESCRIPTION OF THE PREFERRED EMBODIMENTS

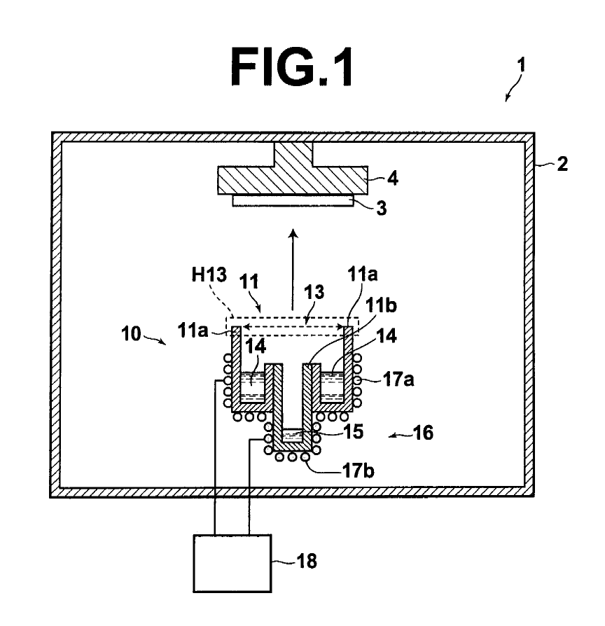

Hereinafter, embodiments of the present invention will be described with reference to the drawings. FIG. 1 is a schematic diagram illustrating the schematic structure of a vacuum vapor deposition apparatus 1 for forming a film on a substrate by heating vapor deposition materials to evaporate and deposit them on a substrate.

The vacuum vapor deposition apparatus 1 includes a processing chamber 2, a substrate holder 4 disposed on the upper inner surface of the processing chamber 2 for holding a substrate 3, and an evaporation device 10 for evaporating vapor deposition materials by heating according to a first embodiment of the invention.

The evaporation device 10 for evaporating vapor deposition materials of this embodiment includes deposition vessels 11a and 11b that respectively contain two different vapor deposition materials 14 and 15, and a heating unit 16 for heating the deposition vessels 11a and 11b. The heating unit 16 heats the deposition vessels 11a and 11b, thereby heating the vapor deposition materials 14 and 15 so that they melt and evaporate. The heating unit 16 includes heaters 17a and 17b respectively disposed around the deposition vessels 11a and 11b, and a power supply connected to the heaters 17a and 17b via wire leads. The heating unit 16 further includes a temperature controlling unit 18 for controlling the temperature of each of the heaters 17a and 17b. The vapor deposition materials 14 and 15 are shown in the drawing in a melted state. In the drawing, supporting members for supporting the deposition vessels and the heaters are omitted.

The heaters 17a and 17b of the heating unit 16 are formed by sheath heaters, which are disposed around the deposition vessels 11a and 11b, respectively. The temperature controlling unit 18 controls the temperature of each of the heaters 17a and 17b so that heating of the deposition vessels 11a and 11b can be controlled independently from each other. A shielding plate against radiant heat may optionally be disposed around the heaters so that the radiant heat from the heaters does not reach the substrate 3.

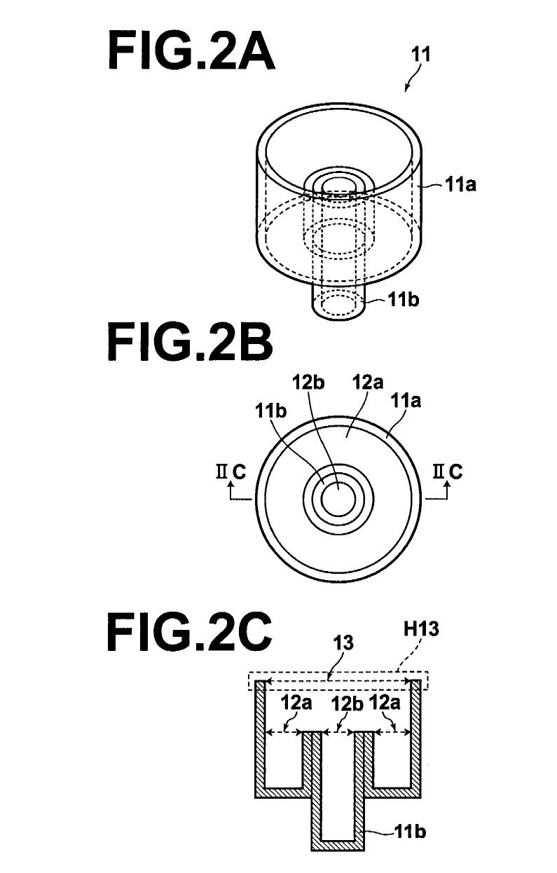

FIGS. 2A-2C illustrate details of the deposition vessels 11a and 11b, and FIG. 2A is a perspective view, FIG. 2B is a plan view and FIG. 2C is a sectional view taken along line II C-II C in FIG. 2B. The deposition vessels 11a and 11b has a common opening 13, through which the vapor deposition materials 14 and 15 evaporated in the deposition vessels 11a and 11b exit together.

The deposition vessels 11a and 11b are formed by two containers respectively containing two different vapor deposition materials 14 and 15, that is, the inner circumferential wall of the doughnut-shaped deposition vessel 11a contacts the outer circumferential wall of the cylindrical deposition vessel 11b over a predetermined area from the top of the outer circumferential wall of the deposition vessel 11b in the depth direction of the vessel. The deposition vessel 11b has a circular opening 12b, and the deposition vessel 11a has a doughnut-shaped opening 12a. The outer circumferential wall of the deposition vessel 11a is higher than the inner circumferential wall thereof. Thus, the circular opening formed by the upper edge (a common opening area H13) of the outer circumferential wall forms a common opening 13, through which the vapor deposition materials 14a and 14b evaporated in the deposition vessels 11a and 11b exit together.

According to the above-described structure, the deposition vessels 11a and 11b containing the vapor deposition materials 14 and 15 are placed in the processing chamber 2 during deposition, and the deposition vessels 11a and 11b are heated by the heaters 17a and 17b in the vacuum processing chamber 2. The thus heated vapor deposition materials 14 and 15 in the deposition vessels 11a and 11b melt and evaporate. The evaporated vapor deposition materials 14 and 15 reach the substrate 3 to form a film thereon. It should be noted that, in practice, a shutter (not shown) is provided between the deposition vessels 11a and 11b and the substrate 3. The shutter is closed during an early stage of the heating of the vapor deposition materials, and is opened to carry out deposition when the heating goes on and a steady state has been reached.

In this embodiment where the evaporation device has the common opening 13 through which the vapor deposition materials 14 and 15 evaporated in the deposition vessels 11a and 11b exit together, the vapor deposition materials 14 and 15 travel the same distance from the common opening 13 to each point on the deposition substrate, thereby allowing formation of a deposited film having a uniform component ratio of the compound of the vapor deposition materials 14 and 15.

Further, heating of the deposition vessels containing different vapor deposition materials by the above-described heating unit 16 can be controlled independently from each other. Therefore, an evaporation amount of each of the vapor deposition materials 14 and 15 evaporated by the heating can individually be controlled, thereby facilitating control of the component ratio of the compound of the vapor deposition materials 14 and 15 forming the deposited film.

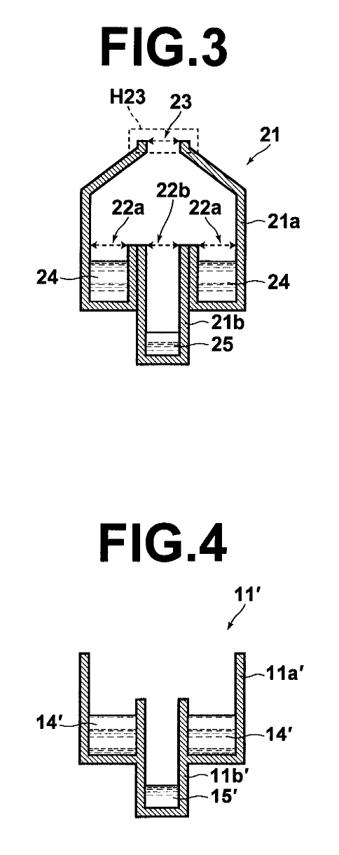

In the above-described embodiment, the common opening 13 is provided separately from the openings 12a and 12b of the deposition vessels 11a and 11b, as shown in FIG. 2. However, the common opening may have any form as long as the vapor deposition materials evaporated in the more than one deposition vessels exit together through the common opening, and may take a form as in a modification shown in FIG. 3. Similarly to the deposition vessels shown in FIG. 2, deposition vessels shown in FIG. 3 include a doughnut-shaped deposition vessel 21a and a cylindrical deposition vessel 21b, which are disposed such that the inner circumferential wall of the deposition vessel 21a contacts the outer circumferential wall of the deposition vessel 21b over a predetermined area from the top of the outer circumferential wall of the deposition vessel 21b in the depth direction of the vessel. However, the diameter of the outer circumferential wall of the deposition vessel 21a is gradually reduced toward the top so that an opening 23 having the substantially same size as an opening 22b of the deposition vessel 21b is formed at the top of the outer circumferential wall (a common opening area H23) right above the opening 21b. The opening 23 is the common opening, through which vapor deposition materials 24 and 25 having evaporated in the deposition vessels 21a and 21b and passed through their respective openings 22a and 22b exit together.

The deposition vessels of the above-described embodiment are formed by separate deposition vessels containing different vapor deposition materials which are combined together to have a common opening. However, as in a modification shown in FIG. 4, the deposition vessels containing different vapor deposition materials may be integrally formed.

It should be noted that, in the first embodiment where the deposition vessels have the common opening, the number, shape and size of the common opening is not particularly limited, and the outer shape of the deposition vessels is not limited to the cylindrical shape.

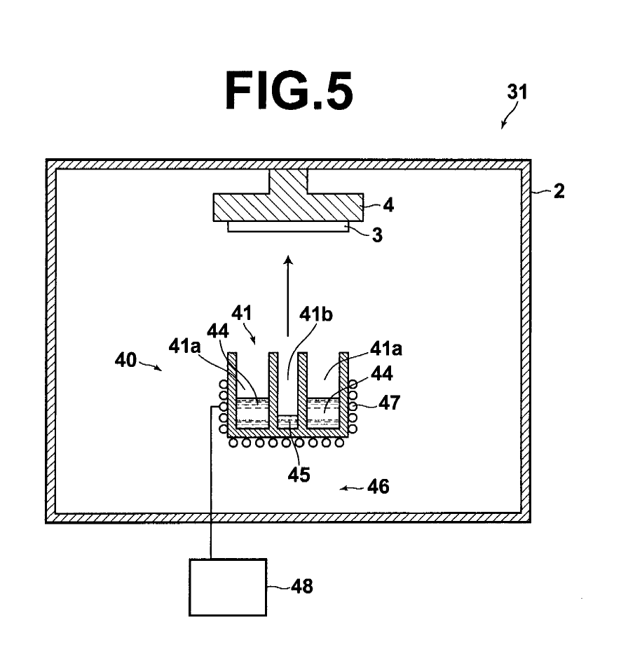

FIG. 5 is a schematic diagram illustrating the schematic structure of a vapor deposition apparatus 31 including an evaporation device for evaporating vapor deposition materials according to a second embodiment of the invention. The vapor deposition apparatus 31 includes the processing chamber 2, the substrate holder 4 disposed on the upper inner surface of the processing chamber 2 for holding the substrate 3, and an evaporation device 40 for evaporating vapor deposition materials by heating according to the second embodiment of the invention.

The evaporation device 40 of this embodiment includes deposition vessels 41a and 41b that respectively contain two different vapor deposition materials 44 and 45, and a heating unit 46 for heating the deposition vessels 41a and 41b. The heating unit 46 heats the deposition vessels 41a and 41b, thereby heating the vapor deposition materials 44 and 45 so that they melt and evaporate. The heating unit 46 includes a heater 47 disposed around the deposition vessels 41a and 41b, and a power supply connected to the heater 47 via a wire lead. The heating unit 46 further includes a temperature controlling unit 48 for controlling the temperature of the heater 47. The vapor deposition materials 44 and 45 are shown in the drawing in a melted state. In the drawing, supporting members for supporting the deposition vessels and the heater are omitted.

The heater 47 of the heating unit 46 is formed by a sheath heater, which is disposed around the deposition vessels 41a and 41b and adjacent to the side and bottom surfaces of the deposition vessel 41a and the bottom surface of the deposition vessel 41b. The temperature controlling unit 48 controls the temperature of the heater 47, thereby controlling heating of the vapor deposition materials 44 and 45 contained in the deposition vessels 41a and 41b. A shielding plate against radiant heat may optionally be disposed around the heater so that the radiant heat from the heater does not reach the substrate 3.

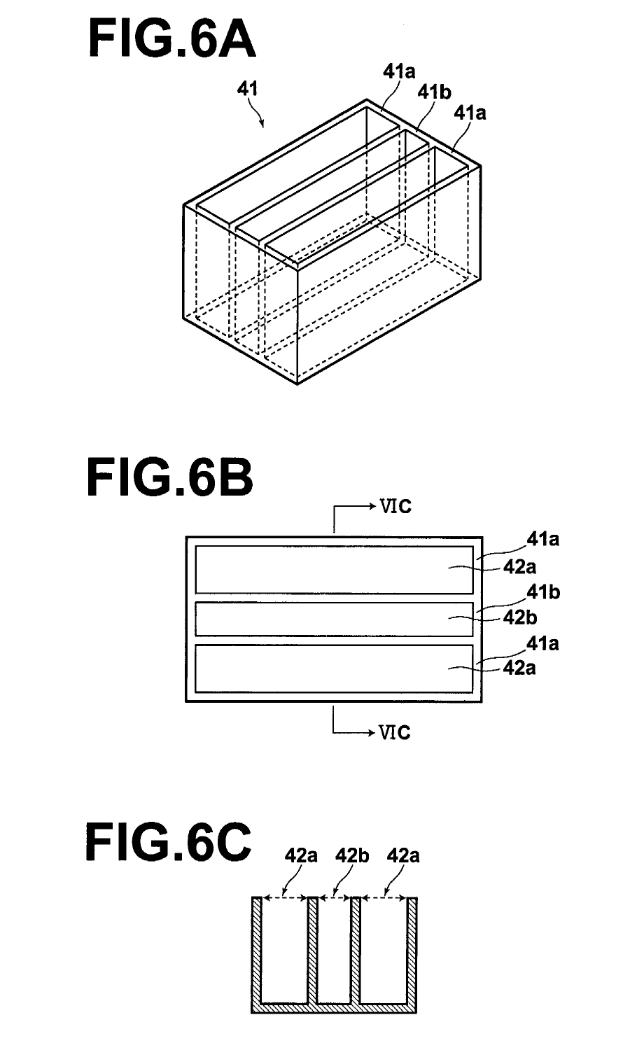

FIGS. 6A-6C illustrate details of the deposition vessels 41a and 41b, and FIG. 6A is a perspective view, FIG. 6B is a plan view and FIG. 6C is a sectional view taken along line VIC-VIC in FIG. 6B. The deposition vessels 41a and 41b respectively contain the vapor deposition materials 44 and 45. The deposition vessels 41a and 41b are integrally formed such that the rectangular deposition vessel 41b is positioned at the center of the rectangular deposition vessel 41a. The deposition vessels 41a and 41b have their respective openings 42a and 42b arranged side by side, through which the vapor deposition materials 44 and 45 evaporated in the deposition vessels 41a and 41b respectively exit.

Since the rectangular deposition vessel 41b is disposed at the center of the rectangular deposition vessel 41a, the deposition vessel 41a is divided into two sections at opposite sides of the deposition vessel 41b. These two sections of the deposition vessel 41a contain the same vapor deposition material 44. Further, the two openings 42a, 42a of the deposition vessel 41a are positioned at opposite sides of the opening 42b of the deposition vessel 41b so that the openings 42a, 42b, 42a are arranged side by side.

The deposition vessels 41a and 41b containing the vapor deposition materials 44 and 45 having the above-described structure are placed in the processing chamber 2 during deposition, and the deposition vessels 41a and 41b are heated by the heater 47 in the vacuum processing chamber 2. The thus heated vapor deposition materials 44 and 45 in the deposition vessels 41a and 41b melt and evaporate. The evaporated vapor deposition materials 44 and 45 reach the substrate 3 to form a film thereon. It should be noted that, in practice, a shutter (not shown) is provided between the deposition vessels 41a and 41b and the substrate 3. The shutter is closed during an early stage of the heating, and is opened to carry out deposition when the heating goes on and a steady state has been reached.

In this embodiment where the evaporation device has the side-by-side openings of the deposition vessels containing the different vapor deposition materials, the vapor deposition materials 44 and 45 travel substantially the same distance from the openings 42a and 42b of the deposition vessels 41a and 41b to each point on the deposition substrate, thereby allowing formation of a deposited film having a highly uniform component ratio of the compound of the vapor deposition materials 44 and 45.

Further, by controlling the temperature of the heater 47 with the temperature controlling unit 48, heating of the vapor deposition materials 44 and 45 contained in the deposition vessels 41a and 41b can be controlled. In a case where deposition is carried out with the vapor deposition materials 44 and 45 being heated to evaporate under the same heating condition, evaporation amounts of the vapor deposition materials 44 and 45 can be controlled by adjusting areas of evaporating surfaces of the vapor deposition materials 44 and 45 contained in the deposition vessels 41a and 41b by adjusting, for example, the sizes of the deposition vessels 41a and 41b in plan view, thereby controlling the component ratio of the deposited film of the compound of the vapor deposition materials 44 and 45.

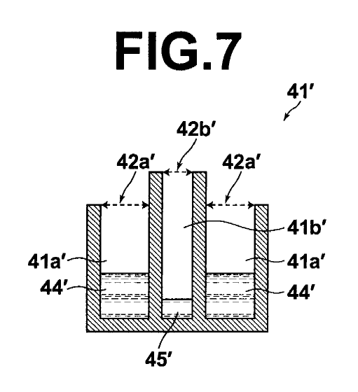

In the above-described embodiment, the openings 42a, 42b, 42a, through which the vapor deposition materials 44 and 45 evaporated in the deposition vessels 41a and 41b respectively exit, are arranged side by side at substantially the same height, as shown in FIG. 6. However, as in a modification shown in FIG. 7, the openings may be positioned at different heights as long as they are arranged side by side in a plan view.

It should be noted that the openings of the deposition vessels containing different materials may not necessarily in complete contact with each other. The openings may be slightly spaced from each other within a range where they can be considered as substantially contacting each other.

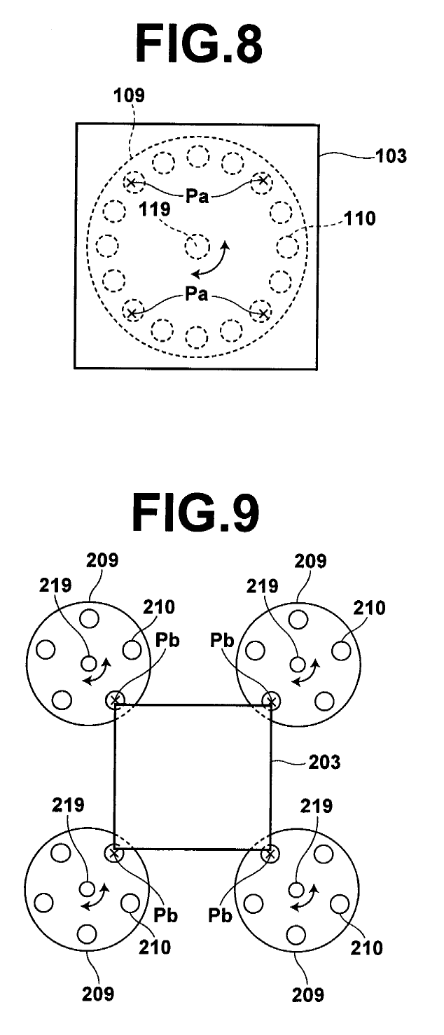

Next, with reference to FIGS. 8 and 9, embodiments of vapor deposition using the evaporation device for evaporating vapor deposition materials of the invention will be explained. In these embodiments, multiple evaporation devices of the invention are placed at the same time in the processing chamber of the vapor deposition apparatus. Generally, in a case where deposition is carried out on a large-area substrate, influence of the uneven film thickness distribution in the radial direction from the evaporation source is enhanced, and it is more difficult to obtain a uniform film than in a case of deposition on a small-area substrate. Therefore, as shown in the layouts of the substrate and the evaporation devices within the vapor deposition apparatus in FIGS. 8 and 9, the multiple evaporation devices of the invention are placed so that deposition is carried out using the multiple evaporation devices at the same time to form a uniform vacuum-deposited film of a compound of more than one vapor deposition materials on the large-area substrate.

In the embodiment shown in FIG. 8, twelve evaporation devices 110 for evaporating vapor deposition materials of the invention are placed on a rotating table 109 at regular intervals along the same circumference of a circle around the rotational axis 119. The rotating table 109 is positioned to face the substrate 103 such that four out of the twelve evaporation devices 110 on the rotating table 109 are placed at four evaporation source positions Pa in the vicinity of four corners of the substrate 103.

Further, in the embodiment shown in FIG. 9, five evaporation devices 210 for evaporating vapor deposition materials are placed on each of four rotating tables 209 at regular intervals along the same circumference of a circle around the rotational axis 219. The rotating tables 209 are positioned at four points in the same plane facing the substrate 203 such that one of the five evaporation devices 210 on each rotating table 209 is placed at one of four evaporation source positions Pb.

In the embodiments shown in FIGS. 8 and 9, evaporation source positions Pa, Pb are positions for the evaporation sources to obtain a most uniform deposited film on a substrate, which are found by numerical calculation or the like. Optimal positions and the number of optimal positions for the evaporation devices vary depending on conditions such as the size and shape of the substrate and the distance from the evaporation devices to the substrate. In this embodiment, the evaporation source positions Pa, Pb found through numerical calculation for each of the rectangular substrates 103, 203, which are almost square, are four positions in the vicinity of the four corners of the substrate in the same plane facing the substrate, as shown in FIGS. 8 and 9.

During deposition, the above-described rotating table 109 or the rotating tables 209 is/are rotated around the rotational axis 119 or the rotational axes 219 by a rotary driving means (not shown), and the four evaporation devices used as the evaporation sources among the evaporation devices 110 or 210 placed on the rotating table 109 or the rotating tables 209 can be sequentially moved into the positions Pa or Pb. In this manner, film formation according to a desired vapor deposition process can be continued using all the film-forming materials contained in the evaporation devices 110 or 210 placed on the rotating table 109 or the rotating tables 209 while the vacuum state of the deposition chamber is maintained.

Next, an embodiment of a radiographic image detector using the vapor deposition apparatus including the evaporation device for evaporating vapor deposition materials of the invention will be explained. The radiographic image detector is used, for example, in an X-ray imaging apparatus. The radiographic image detector includes an electrostatic recording unit having a photoconductive layer, which becomes conductive when being exposed to radiation. When radiation carrying image information is applied to the electrostatic recording unit, the image information is recorded and the electrostatic recording unit outputs an image signal representing the recorded image information. Examples of the radiographic image detector includes a so-called optical reading radiographic image detector, which reads the image information using a semiconductor material that generates electric charges when being exposed to light, and a TFT radiographic image detector, which stores electric charges generated by exposure to the radiation, and reads the image information represented by the stored electric charges by turning on/off electrical switches such as a thin film transistor (TFT) corresponding to pixels of the image one by one.

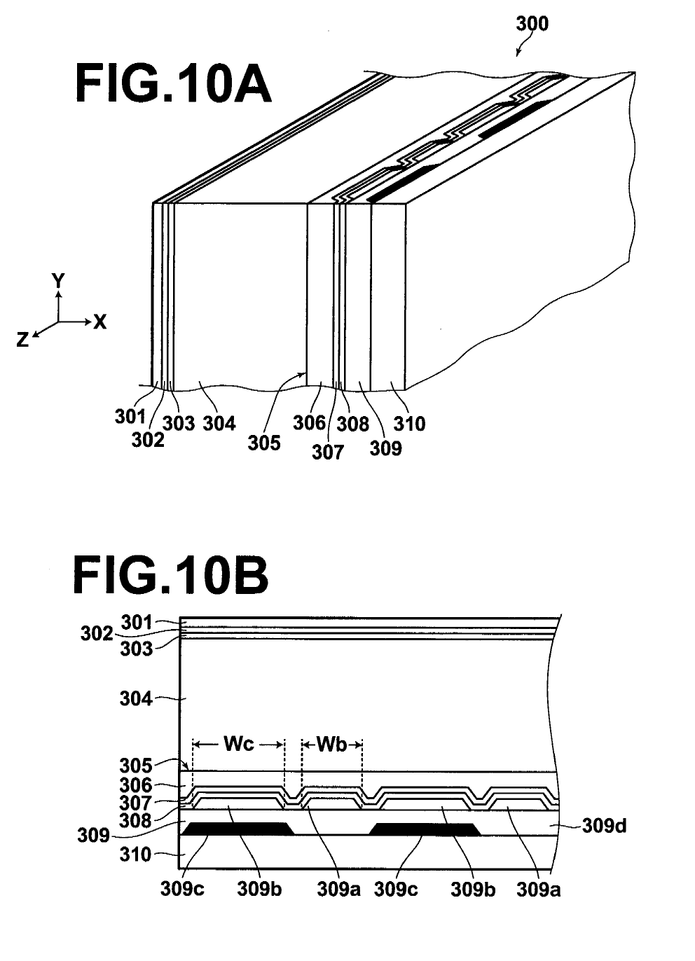

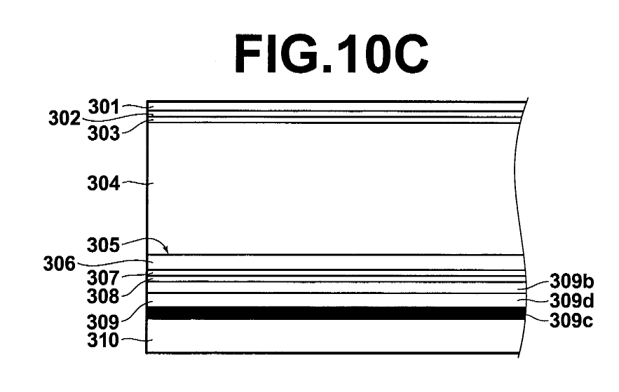

First, details of the optical reading radiographic image detector will be explained. FIG. 10A is a perspective view illustrating the schematic structure of an optical reading radiographic image detector 300, FIG. 10B illustrates the X-Z cross-section of the radiographic image detector 300 and FIG. 10C illustrates the X-Y cross-section of the radiographic image detector 300. The radiographic image detector 300 includes: a first electrode layer 301 which transmits recording light carrying a radiographic image, such as an X-ray image, which has transmitted through the subject; a photoconductive recording layer 304 which generates charge pairs when being exposed to the recording light transmitted through the first electrode layer 301 and thus becomes conductive; a photoconductive reading layer 306 which generates charge pairs when being exposed to reading light and thus becomes conductive; a second electrode layer 309 formed by first transparent linear electrodes 309a, second transparent linear electrodes 309b, light blocking films 309c and an insulating layer 309d; and a substrate 310 which transmits the reading light, which are disposed in this order.

The radiographic image detector 300 further includes a hole injection blocking layer 308 which prevents hole injection from the transparent linear electrodes 309a and 309b, and an electron injection blocking layer 302 which prevents electron injection from the first electrode layer 301 when a high voltage is applied.

The radiographic image detector 300 further includes a crystallization preventing layer 303 disposed between the electron injection blocking layer 302 and the photoconductive recording layer 304 for preventing crystallization of the photoconductive recording layer 304, and a crystallization preventing layer 307 disposed between the hole injection blocking layer 308 and the photoconductive reading layer 306 for preventing crystallization of the photoconductive reading layer 306.

Furthermore, a charge accumulator 305 is formed at the interface between the photoconductive recording layer 304 and the photoconductive reading layer 306. The charge accumulator 305 is distributed two-dimensionally, and accumulates electric charges having a polarity of a latent image (hereinafter referred to as a latent image polarity) that carries a radiographic image generated at the photoconductive recording layer 304.

The size (area) of the radiographic image detector 300 may, for example, be 20 cm×20 cm or more, and if the radiographic image detector 300 is used for chest X-ray imaging, it may have an effective size of about 43 cm×43 cm.

Typical examples of the hole injection blocking layer 308 include CeO₂ and ZnS. The hole injection blocking layer 308 may be formed by a single layer, or may be formed by two or more layers for enhancing hole blocking capability (for reducing dark current). The thickness of the hole injection blocking layer 308 may be in a range from 20 nm to 100 nm.

Examples of the electron injection blocking layer 302 include Sb₂S₃ and organic compounds. The electron injection blocking layer 302 may also be formed by a single layer or two or more layers.

Examples of the crystallization preventing layers 303 and 307 includes binary compounds such as Se—As, Se—Ge and Se—Sb or ternary compounds such as Se—Ge—Sb, Se—Ge—As and Se—Sb—As, which have high crystallization temperatures.

As the substrate 310, a substrate which is transparent to the reading light can be used.

The photoconductive recording layer 304 may be formed by a photoconductive material containing a-Se (amorphous selenium) as the main component.

The photoconductive reading layer 306 may be made of a photoconductive material such as a-Se doped with 10-200 ppm of Cl, which provides a large difference between mobility of negative charges at the first electrode layer 301 and mobility of charges having a reverse polarity, i.e., positive charges, or a photoconductive material containing Se as the main component such as Se—Ge, Se—Sb or Se—As.

The thickness of the photoconductive recording layer 304 may be in a range from 50 μm to 1000 μm for providing sufficient absorption of an electromagnetic wave for recording. The thickness of the photoconductive reading layer 306 may be ½ or less of the thickness of the photoconductive recording layer 304, or may be 1/10 or less, or even 1/100 or less, since the thinner reading layer provides better response for reading.

It should be noted that the above-described materials for the respective layers are examples of materials that are suitable for causing the first electrode layer 301 to be charged with negative charges and the transparent linear electrodes 309a and 309b of the second electrode layer 309 to be charged with positive charges, the charge accumulator 305 formed at the interface between the photoconductive recording layer 304 and the photoconductive reading layer 306 to accumulate negative charges (which are charges having the latent image polarity), and the photoconductive reading layer 306 to function as a so-called hole transport layer where the mobility of positive charges (which are transporting charges having the reverse polarity) is larger than the mobility of the negative charges (the charges having the latent image polarity). However, the polarities of the electric charges may be opposite from those described-above, and in this case, only a slight modification is needed such that the photoconductive reading layer functioning as the hole transport layer is modified to function as an electron transport layer. Further, the photoconductive reading layer 306 may be made of a material containing a-Se as the main component, and a layer of As₂Se₃, GeSe, GeSe₂, or Sb₂Se₃ may be provided as the charge accumulator 305.

The first electrode layer 301 and the first transparent linear electrodes 309a may be made of any material that transmits the recording light or the reading light. In a case where the first electrode layer 301 and the first transparent linear electrodes 309a are designed to transmit visible light, for example, they may be made of a metal oxide such as SnO₂, ITO (Indium Tin Oxide) or IZO (Indium Zinc Oxide), which are known as light-transmitting thin metal films, or IDIXO (Indium X-metal Oxide available from Idemitsu Kosan Co., Ltd.), which is a light-transmitting amorphous metal oxide and is easy to be etched, and may have a thickness of about 50-200 nm, or a thickness of 100 nm or more. Further, in a case where X-ray is used as the recording light and the X-ray is applied to the photoconductive recording layer 304 from the side of the first electrode layer 301 to record a radiographic image, the first electrode layer 301 needs not to transmit visible light and therefore may be made, for example, of a pure metal such as Al or Au and may have a thickness of 100 nm.

The first transparent linear electrodes 309a of the second electrode layer 309 are arranged in stripes with a pitch of a pixel, which is about 50-250 μm for providing high SNR while maintaining high sharpness for the medical X-ray imaging. The width of each first transparent linear electrode 309a is about 10-200 μm within the range of the pixel pitch. The purposes of forming the electrodes of the second electrode layer 309 in the form of stripe electrodes are to facilitate correction of structural noise, to improve SNR of an image by reducing capacity, to reduce reading time by carrying out parallel reading (mainly in the main scanning direction), and the like.

Further, the second electrode layer 309 includes the second transparent linear electrodes 309b, which serve as a conductor member for outputting electric signals having levels corresponding to amounts of the charges of the latent image polarity accumulated in the charge accumulator 305 formed at the interface between the photoconductive recording layer 304 and the photoconductive reading layer 306. The second transparent linear electrodes 309b are arranged in stripes. The second transparent linear electrodes 309b and the first transparent linear electrodes 309a are alternately disposed in parallel with each other.

The second transparent linear electrodes 309b may be made of the above-described light-transmitting thin metal film. In this case, the first transparent linear electrodes 309a and the second transparent linear electrodes 309b are simultaneously patterned in a single lithography step. In this case, the light blocking films 309c, which are made of a material having low light-transmittance, can be provided on areas on the substrate 310 corresponding to the second transparent linear electrodes 309b such that the areas have a transmittance Pc of 10% or less to the reading light, so that the intensity of the reading light applied to the second transparent linear electrodes 309b is lower than the intensity of the reading light applied to the first transparent linear electrodes 309a and thus no charge pair for taking out signals is generated in areas of the photoconductive reading layer 306 corresponding to the second transparent linear electrodes 309b.

The hole injection blocking layer 308, which is a thin film having a thickness of 100 nm or less, is formed over the first transparent linear electrodes 309a and the second transparent linear electrodes 309b. The first transparent linear electrodes 309a and the second transparent linear electrodes 309b are spaced from each other by a predetermined distance so that they are electrically insulated from each other.

In the radiographic image detector 300, a width Wc of each second transparent linear electrode 309b may be larger than a width Wb of each first transparent linear electrode 309a, and a transmittance Prb to the reading light of the first transparent linear electrodes 309a and a transmittance Prc to the reading light of the second transparent linear electrodes 309b maybe set to satisfy the conditional expression (Wb×Prb)/(Wc×Prc)≧5. In this case, since the width Wc of the second transparent linear electrode 309b is larger than the width Wb of the first transparent linear electrode 309a, the second transparent linear electrodes 309b are also used to form an electric field distribution at the time of recording an electrostatic latent image by connecting the first transparent linear electrodes 309a and the second transparent linear electrodes 309b to each other.

By connecting the first transparent linear electrodes 309a and the second transparent linear electrodes 309b to each other for recording, the electric charges having the latent image polarity are accumulated at positions corresponding to both the first and second transparent linear electrodes 309a and 309b. Then, as the reading light is applied to the photoconductive reading layer 306 through the first transparent linear electrodes 309a at the time of reading, electric charges having the latent image polarity above two second transparent linear electrodes 309b adjacent to each first transparent linear electrode 309a at the opposite sides of the first transparent linear electrode 309a are sequentially read out via the two second transparent linear electrodes 309b. Therefore, in this case, a position corresponding to each first transparent linear electrode 309a forms a pixel center and an extent of a pixel in the direction crossing the first and second transparent linear electrodes 309a and 309b includes the first transparent linear electrode 309a and halves of the two second transparent linear electrodes 309b at the opposite sides of the first transparent linear electrode 309a. Further a conductor member having higher conductivity than that of the first and second transparent linear electrodes 309a and 309b may be provided as a bus line, which extends from each of the first and second transparent linear electrodes 309a and 309b along the length direction thereof.

The light blocking film 309c may not necessarily have insulating properties, and may have a specific resistance of 2×10⁻⁶ Ω·cm or more (and optionally 1×10⁻⁵ Ω·cm or less). For example, the light blocking film 309c can be made of a metal such as Al, Mo or Cr, or an inorganic material such as MOS₂, WSi₂ or TiN. In the case of such inorganic materials, the light blocking film 309c may have a specific resistance of 1 Ω·cm or more.

In a case where the light blocking film 309c is made of a conductive material such as a metal, an insulator is provided between the light blocking film 309c and the second transparent linear electrodes 309b to avoid direct contact therebetween. The radiographic image detector 300 of this embodiment includes as the insulator the insulating layer 309d made of SiO₂ or the like between the reading photoconductive layer 306 and the substrate 310. The thickness of the insulating layer 309d may be in a range from about 0.01 to 10 μm.

The light blocking film 309c may be formed to have a thickness that provides an intensity Ub of the reading light applied to the first transparent linear electrodes 309a and an intensity Uc of the reading light applied to second transparent linear electrodes 309b satisfying the conditional expression Ub/Uc≧5. The value of the right-hand side of the expression may optionally be 8, and further optionally be 12.

Further, a width Wd of the light blocking film 309c, the width Wc of the second transparent linear electrode 309b and a space Wbc between the first transparent linear electrode 309a and the second transparent linear electrode 309b may satisfy the conditional expression Wc≦Wd≦(Wc+2×Wbc). This conditional expression indicates that the light blocking films 309c completely cover at least the second transparent linear electrodes 309b and ensure at least areas of the width Wb of the first transparent linear electrodes 309a as the areas transmitting the reading light so that the light blocking films 309c do not cover areas corresponding to the first transparent linear electrode 309a. However, the conditional expression (Wc+Wbc/2)≦Wd≦(Wc+Wbc) may optionally be satisfied since the light blocking films 309c covering only the extent of the width Wc of the second transparent linear electrodes 309b may not provide sufficient light blocking effect, and an amount of the reading light transmitted through only the areas corresponding to the width Wb of the first transparent linear electrodes 309a and reaching the first transparent linear electrodes 309a may not be sufficient.

Among the layers forming the radiographic image detector 300 explained above, the crystallization preventing layer 303, the photoconductive recording layer 304, the photoconductive reading layer 306 and the crystallization preventing layer 307, for example, can be formed with the evaporation device for evaporating vapor deposition materials of the invention.

Specifically, for the respective layers to be formed, the evaporation devices containing vapor deposition materials for forming their corresponding layers are prepared in the processing chamber of the vapor deposition apparatus. Then, the crystallization preventing layer 307, the photoconductive reading layer 306, the photoconductive recording layer 304 and the crystallization preventing layer 303 are sequentially formed in this order, by using the evaporation devices prepared correspondingly to the respective layers, on the substrate 310 having the second electrode layer 309 and the hole injection blocking layer 308 formed thereon in advance.

In this manner, the radiographic image detector 300 including the crystallization preventing layer 303, the photoconductive recording layer 304, the photoconductive reading layer 306 and the crystallization preventing layer 307, each having a uniform component ratio of a compound of more then one vapor deposition materials, can be produced.

In a case where the charge accumulator 305 formed at the interface between the photoconductive recording layer 304 and the photoconductive reading layer 306 is formed by a layer made of As₂Se₃, GeSe, GeSe₂ or Sb₂Se₃, the charge accumulator 305 can also be formed with the evaporation device of the invention.

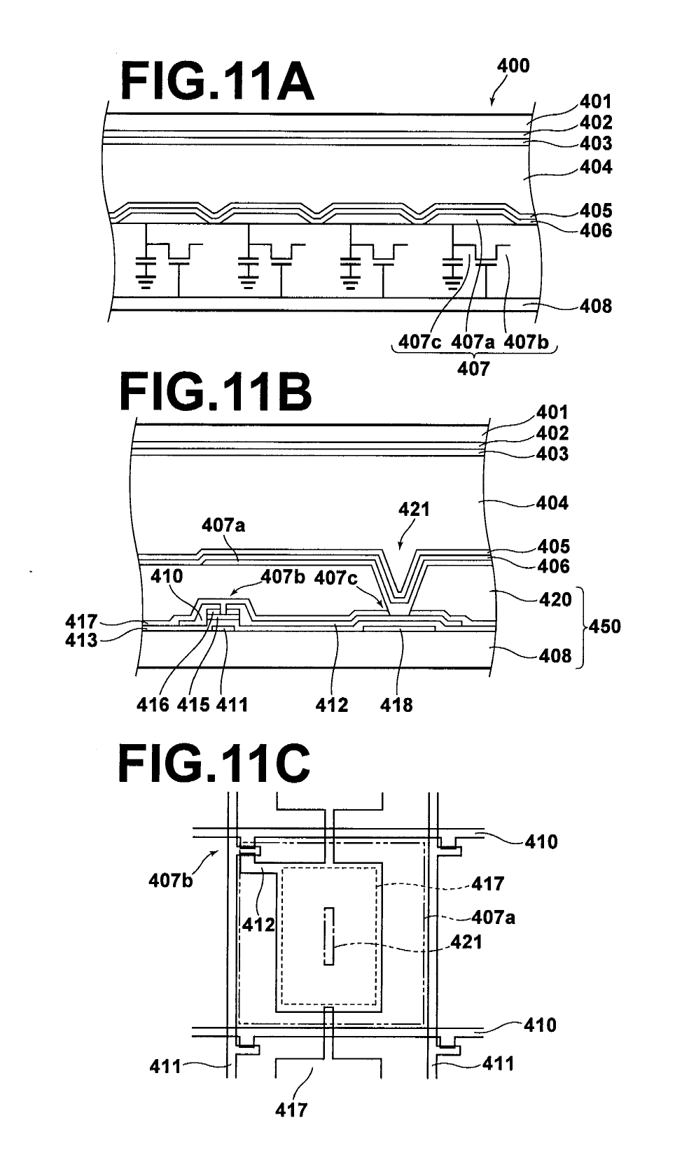

Next, details of the TFT radiographic image detector will be explained with reference to FIGS. 11A, 11B and FIG. 11C. A radiographic image detector 400 shown in FIG. 11A includes: a photoconductive layer 404, which is made, for example, of Se and conducts electromagnetic wave; a single biasing electrode 401 formed above the photoconductive layer 404; and charge collecting electrodes 407a formed below the photoconductive layer 404. Each charge collecting electrode 407a is connected to a charge storing capacitor 407c and a switching element 407b. Further, a hole injection blocking layer 402 is disposed between the photoconductive layer 404 and the biasing electrode 401. Moreover, an electron injection blocking layer 406 is disposed between the photoconductive layer 404 and the charge collecting electrodes 407a. In addition, crystallization preventing layers 403, 405 are disposed respectively between the hole injection blocking layer 402 and the photoconductive layer 404 and between the electron injection blocking layer 406 and the photoconductive layer 404. The charge collecting electrodes 407a, the switching elements 407b and the charge storing capacitors 407c form a charge detecting layer 407, and a glass substrate 408 and the charge detecting layer 407 form an active matrix substrate 450, as described later.

FIG. 11B is a sectional view illustrating the partial structure of the radiographic image detector 400 corresponding to a pixel, and FIG. 11C is a plan view of the same. The size of the pixel shown in FIGS. 11B and 11C is in a range from about 0.1 mm×0.1 mm to about 0.3 mm×0.3 mm. The entire radiographic image detector includes a matrix of pixels ranging from about 500×500 to about 3000×3000 pixels.

As shown in FIG. 11B, the one-pixel portion of the active matrix substrate 450 includes the glass substrate 408, a gate electrode 411, a charge storing capacitor electrode (hereinafter referred to as a Cs electrode) 418, a gate insulation film 413, a drain electrode 412, a channel layer 415, a contact electrode 416, a source electrode 410, an insulation protection film 417, an interlayer insulation film 420 and the charge collecting electrode 407a. The TFT (Thin Film Transistor) switching element 407b is formed by the gate electrode 411, the gate insulation film 413, the source electrode 410, the drain electrode 412, the channel layer 415, the contact electrode 416, and the like, and the charge storing capacitor 407c is formed by the Cs electrode 418, the gate insulation film 413, the drain electrode 412, and the like.

The glass substrate 408 is a support substrate, and may be formed, for example, by an alkali-free glass substrate (such as #1737 available from Corning Incorporated). As shown in FIG. 11C, the gate electrodes 411 and the source electrodes 410 form lattice-like electrode wiring, and the TFT switching element 407b is formed at each intersecting point of the electrode wiring. The source and drain of the switching element 407b are connected to the source electrode 410 and the drain electrode 412, respectively. Each source electrode 410 includes straight-line portions serving as a signal line and extended portions forming the switching elements 407b. The drain electrode 412 is disposed to connect the switching element 407b to the charge storing capacitor 407c.

The gate insulation film 413 is made, for example, of SiNX or SiOX. The gate insulation film 413 is disposed to cover the gate electrode 411 and the Cs electrode 418. An area of the gate insulation film 413 over the gate electrode 411 serves as a gate insulation film in the switching element 407b, and an area of the gate insulation film 413 over the Cs electrode 418 serves as a dielectric layer in the charge storing capacitor 407c. That is, the charge storing capacitor 407c is formed by the overlapping area between the Cs electrode 418, which is formed in the same layer as the gate electrode 411, and the drain electrode 412. It should be noted that the material of the gate insulation film 413 is not limited to SiNX or SiOX, and an anodised film formed by anodizing the gate electrode 411 and the Cs electrode 418 can be used in combination.

The channel layer (i layer) 415 serves as a channel of the switching element 407b, which is a path for electric current between the source electrode 410 and the drain electrode 412. The contact electrode (n+ layer) 416 establishes contact between the source electrode 410 and the drain electrode 412.

The insulation protection film 417 is formed over the source electrodes 410 and the drain electrodes 412, i.e., over the almost entire surface (almost entire area) of the glass substrate 408. In this manner, the drain electrodes 412 and the source electrodes 410 are protected and electrically isolated. Further, the insulation protection film 417 has contact holes 421 in predetermined positions thereof, i.e., positions above portions of the drain electrodes 412 facing the Cs electrodes 418.

The charge collecting electrode 407a is formed by an amorphous transparent conductive oxide film. The charge collecting electrode 407a is formed to fill the contact hole 421, and is disposed above the source electrode 410 and the drain electrode 412. The charge collecting electrode 407a and the photoconductive layer 404 are in electrical communication with each other, so that the electric charge generated in the photoconductive layer 404 can be collected at the charge collecting electrode 407a.

The interlayer insulation film 420 is made of an acrylic resin having photosensitivity and serves to provide electrical isolation of the switching element 407b. The contact hole 421 passes through the interlayer insulation film 420 to allow the charge collecting electrode 407a connecting to the drain electrode 412. As shown in FIG. 11B, the contact hole 421 has an inverse tapered shape.

A high voltage power supply (not shown) is connected between the biasing electrode 401 and the Cs electrode 418. The high voltage power supply applies a voltage between the biasing electrode 401 and the Cs electrode 418 to generate an electric field between the biasing electrode 401 and the charge collecting electrode 407a via the charge storing capacitor 407c. The photoconductive layer 404 and the charge storing capacitor 407c are electrically connected in series, and therefore, when a biasing voltage is applied to the biasing electrode 401, an electric charge (electron-hole pairs) is generated in the photoconductive layer 404. The electrons generated in the photoconductive layer 404 move toward the positive electrode, and the holes move toward the negative electrode. As a result, the electric charge is stored in the charge storing capacitor 407c.

The entire radiographic image detector includes the multiple charge collecting electrodes 407a arrayed one- or two-dimensionally, the multiple charge storing capacitors 407c individually connected to the charge collecting electrodes 407a, and the multiple switching elements 407b individually connected to the charge storing capacitors 407c. With this structure, one- or two-dimensional electromagnetic wave information can be once stored in the charge storing capacitors 407c, and one or two-dimensional electric charge information can be easily read out by sequentially scanning the switching elements 407b.

Next, principle of operation of the radiographic image detector 400 having the above-described structure will be explained. When an X-ray is applied to the photoconductive layer 404 while a voltage is applied between the biasing electrode 401 and the Cs electrode 418, electric charges (electron-hole pairs) are generated in the photoconductive layer 404. Since the photoconductive layer 404 and the charge storing capacitors 407c are electrically connected in series, the electrons generated in the photoconductive layer 404 move toward the positive electrode, and the holes move toward the negative electrode. As a result, electric charges are stored in the charge storing capacitors 407c.

The electric charges stored in the charge storing capacitors 407c can be transferred to the outside via the source electrodes 410 when the switching elements 407b are turned on by signals inputted to the gate electrodes 411. Since the electrode wiring formed by the gate electrodes 411 and the source electrodes 410, the switching elements 407b and the charge storing capacitors 407c are arranged in a matrix, two-dimensional X-ray image information can be obtained by sequentially scanning the signals inputted to the gate electrodes 411 and detecting signals from the source electrodes 410 one by one.

Next, details of the charge collecting electrode 407a will be explained. The charge collecting electrode 407a used in the invention is formed by an amorphous transparent conductive oxide film. The basic composition of the amorphous transparent conductive oxide film material may be indium tin oxide (ITO), indium zinc oxide (IZO), indium germanium oxide (IGO), or the like.

Although various metal films and conductive oxide films may be used as the charge collecting electrode, a transparent conductive oxide film, such as ITO (Indium-Tin-Oxide), is often used for the following reason. If an amount of X-ray applied to the radiographic image detector is large, unnecessary electric charges may be trapped in the semiconductor film (or around the interface between the semiconductor film and an adjacent layer). Such residual charges may be stored for a long time or may move gradually, and may affect subsequent image detections by deteriorating X-ray detection property or producing a residual image (false image). A method for addressing this problem is disclosed in U.S. Pat. No. 5,563,421), in which light is applied to the photoconductive layer from outside to excite the residual charges in the photoconductive layer to remove the residual charges. In this case, the charge collecting electrodes need to be transparent to the applied light for efficiently applying the light to the photoconductive layer from below (through the charge collecting electrodes). Further, in order to increase an area filling factor (filling factor) of the charge collecting electrodes or to shield the switching elements, it is desirable to form the charge collecting electrodes so as to cover the switching elements. In this case, if the charge collecting electrodes are opaque, the switching elements cannot be observed after the charge collecting electrodes are formed. For example, in a case where properties of the switching elements are tested after the charge collecting electrodes are formed, opaque charge collecting electrodes covering the switching elements obstruct observation of defective switching elements with an optical microscope or the like to find out a cause of the defect. Therefore, the transparent charge collecting electrodes are desirable for easy observation of the switching elements after formation of the charge collecting electrodes.

Next, one example of a production process of the radiographic image detector 400 will be explained. First, a metal film of Ta, Al, or the like, is formed on the glass substrate 408 through sputter deposition to a thickness of about 300 nm, and the metal film is patterned into a desired shape to form the gate electrodes 411 and the Cs electrodes 418. Then, the gate insulation film 413 made of SiNX or SiOX is formed through CVD (Chemical Vapor Deposition) to a thickness of about 350 nm over the substantially entire surface of the glass substrate 408 to cover the gate electrodes 411 and the Cs electrodes 418. It should be noted that the material of the gate insulation film 413 is not limited to SiNX or SiOX, and an anodised film formed by anodizing the gate electrodes 411 and the Cs electrodes 418 can be used in combination. Further, the channel layer 415 is formed by forming an amorphous silicon (hereinafter referred to as a-Si) film to a thickness of about 100 nm through CVD and patterning the a-Si film into a desired shape so that the channel layer 415 is disposed above the gate electrodes 411 via the gate insulation film 413. Then, the contact electrodes 416 are formed by forming an a-Si film to a thickness of about 40 nm through CVD and patterning the a-Si film into a desired shape so that the contact electrodes 416 are disposed above the channel layer 415.

Further, a metal film of Ta, Al, or the like, is formed on the contact electrodes 416 through sputter deposition to a thickness of about 300 nm, and the metal film is patterned into a desired shape to form the source electrodes 410 and the drain electrodes 412. Thus, the switching elements 407b, the charge storing capacitors 407c, and the like, are formed on the glass substrate 408. Then, the insulation protection film 417a is formed by forming a film of SiNX through CVD to a thickness of about 300 nm to cover the substantially entire surface of the glass substrate 408. Thereafter, portions of the SiNX film on predetermined areas of the drain electrodes 412 are removed to form the contact holes 421. Subsequently, the interlayer insulation film 420 is formed by forming a film of a photosensitive acrylic resin, or the like, to a thickness of about 3 μm to cover the substantially entire surface of the insulation protection film 417. Then, through photolithographic patterning, the contact holes 421 are formed in the interlayer insulation film 420 at positions corresponding to the contact holes 421 formed in the insulation protection film 417.

Then, the charge collecting electrodes 407a are formed by forming an amorphous transparent conductive oxide film such as ITO (Indium-Tin-Oxide) through sputter deposition to a thickness of about 200 nm over the interlayer insulation film 420 and patterning the amorphous transparent conductive oxide film into a desired shape. At this time, the charge collecting electrodes 407a and the drain electrodes 412 are electrically connected (short-circuited) via the contact holes 421 formed in the insulation protection film 417 and the interlayer insulation film 420. In this embodiment, as described above, the active matrix substrate 450 has a so-called roof structure (mushroom electrode structure) in which the charge collecting electrodes 407a overlap the switching elements 407b from above, however, the active matrix substrate 450 may have a non-roof structure. Further, the switching elements 407b are not limited to an a-Si TFT, and may be formed by a p-Si (polysilicon) TFT.

After the electron injection blocking layer 406 (about 10 to 100 nm, or optionally about 20 to 100 nm) and then the crystallization preventing layer 405 (about 10 to 100 nm) are formed to cover the entire area of the pixel array of the active matrix substrate 450 formed as described above, the photoconductive layer 404 made of a material containing a-Se (amorphous selenium) doped with As, GeSb and conducting electromagnetic wave is formed through vacuum vapor deposition to a thickness of about 0.5 mm to 1.5 mm. Subsequently, the crystallization preventing layer 403 (about 10 to 100 nm) is formed, and the hole injection blocking layer 402 (about 30 to 100 nm) is formed, and finally, the biasing electrode 401 made of Au, Al, or the like, is formed through vacuum vapor deposition to a thickness of about 200 nm over the substantially entire surface of the photoconductive layer 404.

The crystallization preventing layers 403 and 405 can be made, for example, of GeSe, GeSe₂, Sb₂Se₃ or a-As₂Se₃, or a Se—As, Se—Ge or Se—Sb compound. The hole injection blocking layer 402 can be made, for example, of an oxide compound or sulfide compound (ZnS), and maybe formed by ZnS which allows film formation at a low temperature. If the crystallization preventing layer 403 is made of As₂Se₃, it also serves as a hole injection blocking layer, and therefore the separate hole injection blocking layer 402 may not be formed. The electron injection blocking layer 406 may be made of Sb₂S₃, for example.

The photoconductive layer 404 may be made of an amorphous material that has a high dark resistance, well conducts electromagnetic wave when exposed to X-ray, and allows formation of a large-area film through vacuum vapor deposition at a low temperature. As the photoconductive layer 404, an amorphous Se (a-Se) film has been used, however, amorphous Se doped with As, Sb or Ge may be used to provide good thermal stability.

Among the layers forming the radiographic image detector 400 explained above, the crystallization preventing layer 403, the photoconductive layer 404 and the crystallization preventing layer 405, for example, can be formed with the evaporation device for evaporating vapor deposition materials of the invention.

Specifically, for the respective layers to be formed, the evaporation devices containing vapor deposition materials for forming their corresponding layers are prepared in the processing chamber of the vapor deposition apparatus. Then, the crystallization preventing layer 405, the photoconductive layer 404 and the crystallization preventing layer 403 are sequentially formed in this order, by using the evaporation devices prepared correspondingly to the respective layers, on the active matrix substrate 450 having the electron injection blocking layer 406 formed thereon in advance.

In this manner, the radiographic image detector 400 including the crystallization preventing layer 403, the photoconductive layer 404 and the crystallization preventing layer 405, each having a uniform component ratio of a compound formed by more then one vapor deposition materials, can be produced.

The embodiments of the present invention have been explained, however, the invention is not limited to the above-described embodiments, and many variations may be made based on the gist of the invention. For example, although the heating unit in the above embodiments is formed by a sheath heater, the heating unit may be formed by other type of heaters such as a plate or coil heater formed of tantalum or stainless steel or a lamp heater.

Further, a mesh having a mesh size of about 25 μm to 100 μm, for example, may be provided between the opening of the evaporation device and the substrate with the temperature of the mesh being controlled, so that the vapor deposition materials pass through the mesh to reach the substrate 3 and be deposited during the deposition. In this manner, bumping of the deposition materials can be prevented, thereby preventing defects due to bumping in the film formed on the substrate or the like.

The evaporation device for evaporating vapor deposition materials according to one aspect of the invention includes: a plurality of deposition vessels each containing a different vapor deposition material; a heating unit for heating the vapor deposition materials contained in the deposition vessels; and a common opening area including a common opening, the vapor deposition materials evaporated in the deposition vessels exiting together through the common opening. Since the vapor deposition materials evaporated in the deposition vessels exit together through the common opening, the vapor deposition materials travel the same distance from the common opening to each point on the deposition substrate regardless of which deposition vessel each vapor deposition material is contained. Therefore, a deposited film having a uniform component ratio of the compound of the more than one vapor deposition materials can be formed.

The evaporation device for evaporating vapor deposition materials according to another aspect of the invention includes: a plurality of deposition vessels each containing a different vapor deposition material, the deposition vessels having their openings arranged side by side; and a heating unit for heating the vapor deposition materials contained in the deposition vessels. Therefore, the vapor deposition materials travel substantially the same distance from the openings of the deposition vessels to each point on the deposition substrate, thereby improving uniformity in the component ratio of the deposited film of the compound of the more than one vapor deposition materials.

In a case where heating of each deposition vessel containing a different vapor deposition material by the heating unit can be independently controlled in the above-described evaporation devices, an evaporation amount of each vapor deposition material evaporated by heating can be individually controlled. This facilitates control of the component ratio of the deposited film of the compound of the more than one vapor deposition materials.

What is claimed is:

1. An evaporation device for evaporating vapor deposition materials, the device comprising:
a plurality of deposition vessels each containing a different vapor deposition material;
a heating unit for heating the vapor deposition materials contained in the deposition vessels; and
a common opening area including a common opening, the vapor deposition materials evaporated in the deposition vessels exiting together through the common opening.

2. An evaporation device for evaporating vapor deposition materials, the device comprising:
a plurality of deposition vessels each containing a different vapor deposition material, the deposition vessels having their openings arranged side by side; and
a heating unit for heating the vapor deposition materials contained in the deposition vessels.

3. The evaporation device for evaporating vapor deposition materials as claimed in claim 1, wherein heating of each deposition vessel by the heating unit is independently controllable.

4. The evaporation device for evaporating vapor deposition materials as claimed in claim 2, wherein heating of each deposition vessel by the heating unit is independently controllable.
